(19) United States
(12) Patent Application Publication
(10) Pub. No.: US 2007/0048444 A1
(43) Pub. Date: Mar. 1, 2007

(54) MANUFACTURING METHOD OF OPTICAL DISK AND ITS MANUFACTURING APPARATUS

(76) Inventors: Hidetoshi Watanabe, Chiba (JP); Shoji Akiyama, Saitama (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/464,939

(22) Filed: Aug. 16, 2006

(30) Foreign Application Priority Data
Aug. 30, 2005 (JP) P2005-249379
May 24, 2006 (JP) P2006-143766

(51) Int. Cl. B05D 5/06; B05D 3/12; C08F 2/46; B05C 11/02; C23C 14/00

(52) U.S. Cl. 427/162; 427/355; 427/487; 118/50; 427/102; 118/100

(57) ABSTRACT

A manufacturing method of an optical disk in which information recording layers are formed onto a resin layer laminated on a substrate surface. The substrate surface is coated with the resin layer. The substrate and a stamper are arranged into a vacuum chamber so that the resin layer surface and the stamper surface with concave/convex portions face almost in parallel. The chamber is set into an almost vacuum state while holding the facing state of the substrate and the stamper. The chamber is changed from the almost vacuum state to an atmospheric pressure or higher. The substrate and the stamper are overlaid. The stamper is pressed by a differential pressure between the almost vacuum pressure and the atmospheric pressure or higher, thereby adhering the substrate and the stamper and transferring the concave/convex portions to the resin layer. The resin layer with the transferred concave/convex portions is hardened.

### CROSS REFERENCES TO RELATED APPLICATIONS

The present invention contains subject matter related to Japanese Patent Application No.JP 2005-249379 filed on Aug. 30, 2006, and Japanese Patent Application No. JP 2006-143766 filed on May 24, 2006, the entire contents of which being incorporated herein by reference.

### BACKGROUND OF THE INVENTION

1. Field of the Invention

The invention relates to a manufacturing method of an optical disk and its manufacturing apparatus and, more particularly, to a manufacturing method of an optical disk and its manufacturing apparatus which are applied to, for example, a multilayer optical disk having two or more information recording layers.

2. Description of the Related Arts

In recent years, in the optical disk field, the realization of a large recording capacity is demanded. To realize the large recording capacity, it is considered that multilayer optical disks each having a plurality of information recording layers are desirable (refer to Patent Document JP-A-2003-91868). Among them, the optical disk having two information recording layers has a possibility that it is put into practical use first. In the case of a read only optical disk, a reflecting film of silver, aluminum, or the like is formed. In the case of a recordable optical disk, a recording film such as a phase-change type recording film or the like is formed. In the present specification, the reflecting film or the recording film is generally called an information recording layer.

A high-density optical disk has a recording capacity of about 25 Gbytes for a one-side single-layer or about 50 Gbytes for a one-side double-layer. In order to decrease a diameter of a spot of a beam for recording and reproduction, for example, a wavelength of a light source is set to 405 nm and a numerical aperture NA of an objective lens is set to a large value of 0.85.

In the high-density optical disk which has two information recording layers and in which information is read out of one side, an L0 layer as an information recording layer serving as a reference layer is formed at a position of a depth of 0.1 mm (100 μm) when seen from the incident direction of a laser beam and an L1 layer as an information recording layer serving as an additional layer is formed at a position of a depth of 75 μm.

In manufacturing steps of the optical disk having the two information recording layers as mentioned above, first, when a substrate is formed, concave and convex portions of the L0 layer are formed onto one principal plane of the substrate, an intermediate layer made of an ultraviolet hardening type resin is formed onto the L0 layer, and concave and convex portions of the L1 layer are formed onto the intermediate layer. In the case of the read only optical disk, concave/convex portions modulated in accordance with the information to be recorded are formed. In the case of the recordable optical disk, concave/convex portions modulated in accordance with the information to be previously recorded such as addresses, spiral groove, or the like are formed.

The concave/convex portions of the L1 layer are formed by pressing a stamper to the intermediate layer and irradiating ultraviolet rays in the pressing state. In the following explanation, the ultraviolet hardening type resin is properly called a “UV resin”.

As forming methods of the concave/convex portions of the L1 layer in the related art, for example, a roller pressure bonding method, a spin bonding method, a pad pressure bonding—pressure degassing method, an adhering method in a vacuum, and the like have been proposed.

FIGS. 10A to 10D show examples of the forming method of the concave/convex portions of the L1 layer in the related art. FIG. 10A shows the intermediate layer transfer method according to the roller pressure bonding method. In the roller pressure bonding method, first, a surface of a substrate 101a is coated with a UV resin 102a by, for example, a dispensing method or a screen printing method.

Subsequently, a stamper 103a is overlaid onto the UV resin 102a. A pressure is applied to the stamper 103a from a position over the substrate 101a by a roller 104 serving as pressing means. Thus, the concave/convex portions of the stamper 103a are transferred to the UV resin 102a as an intermediate layer. After that, the ultraviolet rays are irradiated to the UV resin 102a by using an ultraviolet irradiator (UV irradiator) U, so that the UV resin 102a is hardened.

According to the roller pressure bonding method, if a resin of low viscosity is used, it is difficult to hold uniformity of a film thickness. Further, resin burs occur frequently in an outer rim edge portion. Moreover, in the case of using a resin of high viscosity or a PSA (Pressure Sensitive Adhesive), since bubbles are easily trapped, it is necessary to raise a pressure of the roller.

FIG. 10B shows the forming method of the concave/convex portions of the L1 layer according to what is called a spin bonding method. As shown in FIG. 10B, according to this forming method, first, a resin 102b in a liquid state is filled between a stamper 103b and a substrate The resin 102b is filled while the substrate 101b is rotated. After the resin 102b was filled, the resin 102b is hardened by irradiating the ultraviolet rays by using the UV irradiator U. Thus, the concave/convex portions of the stamper 103b are transferred to the intermediate layer.

According to the spin bonding method, the resin 102b can be preferably and uniformly filled. However, a resin leakage into the outer rim edge portion, generation of burs, and the like increase. Further, there is such a problem that it is difficult to peel off the stamper 103b.

FIG. 10C shows what is called a pad pressure bonding—pressure degassing method. According to the pad pressure bonding—pressure degassing method, first, a surface of a substrate 101c is preliminarily coated with a PSA 102c. A stamper 103c is overlaid onto the substrate 101c. A pressure is applied to the stamper 103c by a pressure pad 106 serving as pressing means. Moreover, transfer performance is further improved by applying a pressure in a pressure chamber P and the concave/convex portions of the stamper 103c are transferred to the PSA 102c.

The pad pressure bonding—pressure degassing method has such an advantage that the generated bubbles can be fined by applying the pressure. However, according to the pad pressure bonding—pressure degassing method, there is such a tendency that the fine bubbles are diffused into the UV resin 102d. If such a disk is used in the atmosphere, since the fine bubbles are expanded, there is such a problem that it is liable to cause deterioration in quality of the disk such as corrosion of the recording film or the like.

FIG. 10D shows the adhering method in the vacuum. According to the adhering method in the vacuum, a stamper 103d is adhered onto a flat coated UV resin 102d on a substrate 101d by a pressure pad 107 in a vacuum chamber T which has been vacuum-evacuated as shown by an arrow D. Therefore, the concave/convex portions of the stamper 103d are transferred to the UV resin 102d. After that, the ultraviolet rays are irradiated to the UV resin 102d by using the UV irradiator U, so that the UV resin 102d is hardened.

According to the adhering method in the vacuum, by pressing the stamper 103d to the UV resin 102d coated onto the substrate 101d in the vacuum, the concave/convex portions of the stamper 103d are transferred, so that the number of generated bubbles can be reduced. However, there is the following problem.

FIGS. 11A to 11F show a detailed flow of the adhering method in the vacuum. As shown in FIG. 11A, the concave/convex portions are formed on one principal plane of the substrate 101d by injection molding in the substrate molding step.

Subsequently, the reflecting film or the recording film is formed as an information recording layer onto the substrate. In the film forming step of the information recording layer, as shown in FIG. 11B, an information recording layer 111 is formed as a film onto the concave/convex portions formed on the substrate 101d in the vacuum chamber T by, for example, a sputtering method. In the diagram, S denotes an incident direction of a sputtering atom.

Subsequently, in a UV resin coating step, as shown in FIG. 11C, the UV resin 102d is coated flat by a spin-coating method. At this time, in order to uniform a thickness of coating film in a disk radial direction, the coating process is executed while irradiating infrared rays from the inner rim toward the outer rim by using an IR lamp I.

Subsequently, in a transfer step of the concave/convex portions, as shown in FIG. 11D, in the vacuum chamber T, in the state where the transparent resin stamper 103d is disposed so as to face the UV resin 102d, by applying a pressure to the stamper 103d from an upper position, the stamper 103d is adhered to the UV resin 102d.

Subsequently, as shown in FIG. 11E, the state where the stamper 103d has been adhered is held and the ultraviolet rays are irradiated to the UV resin 102d from an upper position of the substrate 101d by using the UV irradiator U, so that the UV resin 102d is hardened. After that, as shown by arrows, the stamper 103d is peeled off from the substrate 101d. In this manner, as shown in FIG. 11F, the concave/convex portions of the stamper are transferred to the UV resin 102d as an intermediate layer.

FIG. 12 shows a layout of the stamper 103d and the substrate 101d before the stamper 103d is adhered in the concave/convex portions transfer step shown in FIG. 11D. The stamper 103d is arranged so as to face the substrate 101d coated with the UV resin 102d almost in parallel with the substrate 101d. The stamper 103d is arranged at a position where it is away from the substrate 101d by a predetermined interval. The substrate 101d is supported to a large-diameter portion of a two-stage centering pin 122. The stamper 103d is supported to a small-diameter portion of the two-stage centering pin 122.

After the stamper 103d and the substrate 101d were arranged as mentioned above, the stamper 103d is pressed by, for example, a center bush 121 as pressing means. The two-stage centering pin 122 is moved downward. The stamper 103d is pressed to the UV resin 102d. The concave/convex portions of the stamper 103d are transferred to the UV resin 102d.

According to the foregoing adhering method in the vacuum, the number of generated bubbles upon transfer can be reduced. However, when the stamper 103d is adhered to the substrate 101d, since there are various entering methods of the bubbles in dependence on a form of a relative deformation of a shape of the stamper 103d to the substrate 101d, there is such a problem that it is difficult to certainly suppress the generation of the bubbles.

For example, as shown in FIG. 13A, if the apparatus enters the state where the adhesion from the inner rim portion and the adhesion from the outer rim portion toward the middle portion progress almost simultaneously, forces occur in directions shown by arrows 140a in the diagram. Thus, bubbles 141a are generated in the middle portion of a disk 131a as shown in FIG. 13B.

If a surface of the stamper 103d and a surface of the UV resin 102d are simultaneously adhered as shown in FIG. 14A, forces occur in directions shown by arrows 140b. That is, the forces act in the random directions. Consequently, as shown in FIG. 14B, bubbles 141b are generated at random and aggregated in a disk 131b. The state of the bubbles 141b is a network-like state of bubbles 142.

Further, as shown in FIG. 15A, bubbles 141c are also generated by an influence of a warp of the stamper 103d. In this case, since the air is liable to enter from the outer rim of the disk, the bubbles 141c are generated in a whole disk 131c as shown in FIG. 15B.

On the other hand, there is a case where forces act accidentally in the directions shown by arrows 140d as shown in FIG. 16A, bubbles are generated only in the outermost rim of a disk 131d, and the generation of the bubbles can be suppressed as shown in FIG. 16B. In such a case, the stamper 103d is come into contact with the surface of the UV resin 102d since the middle portion is bent, and the adhesion in the inner rim direction from the middle portion and the adhesion in the outer rim direction from the middle portion occur simultaneously.

### SUMMARY OF THE INVENTION

However, in the adhering method in the vacuum, since the operation of the stamper which can suppress the generation of the bubbles as shown in FIG. 16A occurs accidentally and lacks reproducibility, it is difficult to certainly suppress the generation of the bubbles and it is difficult to stably provide the optical disks of high quality.

It is, therefore, desirable to provide a manufacturing method of an optical disk and its manufacturing apparatus, in which the generation of bubbles can be certainly suppressed and the optical disks of high quality can be stably provided.

According to an embodiment of the present invention, there is provided a manufacturing method of an optical disk in which an information recording layer is formed onto a resin layer laminated on one surface of a substrate, comprising the steps of:

coating the resin layer onto the surface of the substrate;

arranging the substrate and a stamper into a chamber so that one surface of the resin layer and one surface of the stamper on which concave/convex portions have been formed face almost in parallel;

setting the chamber into an almost vacuum state while holding the facing state of the substrate and the stamper;

changing the chamber from the almost vacuum state to a state of an atmospheric pressure or higher, overlaying the substrate and the stamper, and pressing the stamper by a differential pressure between a pressure in the almost vacuum state and a pressure which is equal to or higher than the atmospheric pressure, thereby adhering the substrate and the stamper and transferring the concave/convex portions to the resin layer; and

hardening the resin layer to which the concave/convex portions have been transferred.

According to another embodiment of the present invention, there is provided a manufacturing apparatus of an optical disk, comprising:

supporting means holding a substrate coated with a resin layer on one surface and a stamper in a chamber so that the resin layer and one surface of the stamper on which concave/convex portions have been formed face; and

control means setting the chamber into an almost vacuum state while holding the facing state of the substrate and the stamper and changing the chamber from the almost vacuum state to a state of an atmospheric pressure or higher,

wherein by cancelling the holding state of the stamper and the substrate synchronously with the change in air pressure, the substrate and the stamper are overlaid, and by pressing the stamper by a differential pressure between a pressure in the almost vacuum state and a pressure which is equal to or higher than the atmospheric pressure, the substrate and the stamper are adhered and the concave/convex portions are transferred to the resin layer.

According to the embodiments of the present invention, there is such an effect that the generation of the bubbles can be certainly suppressed when the concave/convex portions of the stamper are transferred to an intermediate layer.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a cross sectional view showing a structure of an example of an optical disk according to an embodiment of the invention;

FIGS. 2A to 2L are schematic diagrams showing a manufacturing method of the optical disk according to the embodiment of the invention;

FIGS. 3A to 3C are schematic diagrams showing an outline of transfer of a differential pressure laminating method;

FIGS. 4A and 4B are schematic diagrams showing a more specific example of the differential pressure laminating apparatus and a concave/convex portions forming step;

FIGS. 5A and 5B are schematic diagrams showing a more specific example of the differential pressure laminating apparatus and the concave/convex portions forming step;

FIG. 6 is a schematic diagram showing the operation of an apparatus when a stamper is peeled off;

FIGS. 7A and 7B are schematic diagrams showing an outline of the transfer using a curved stamper;

FIGS. 8A and 8B are schematic diagrams for use in explanation of the differential pressure laminating method of forcedly pressurizing;

FIG. 9 is a cross sectional view showing another example of an optical disk according to the embodiment of the invention;

FIGS. 10A to 10D are schematic diagrams showing an example of a forming method of concave/convex portions of an L1 layer in the related art;

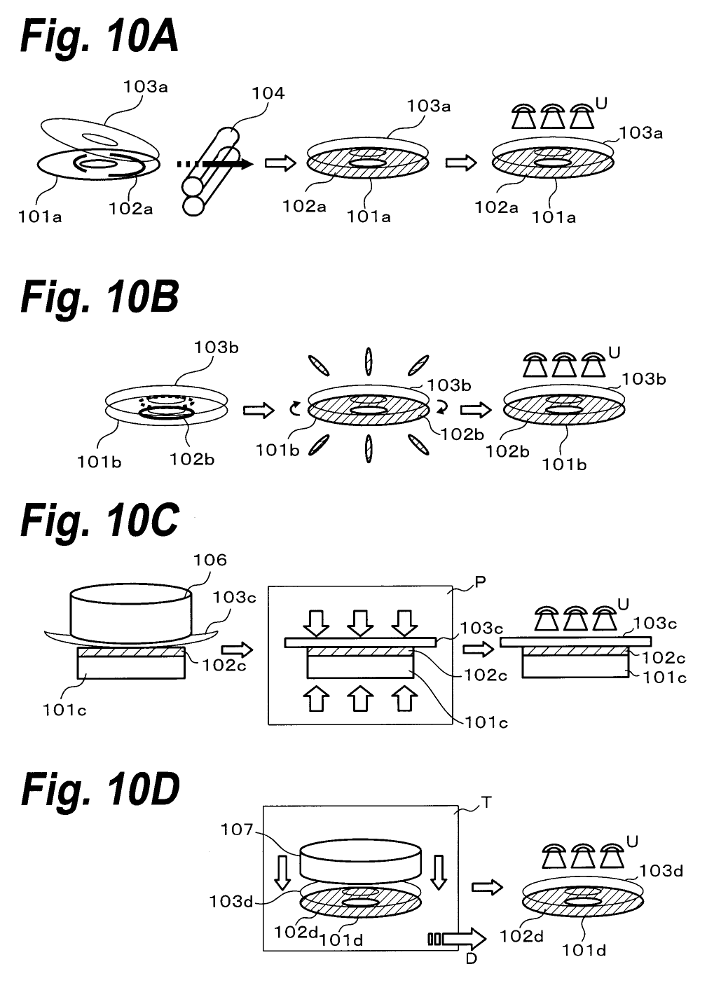

FIGS. 11A to 11F are schematic diagrams showing a detailed flow of an adhering method in a vacuum;

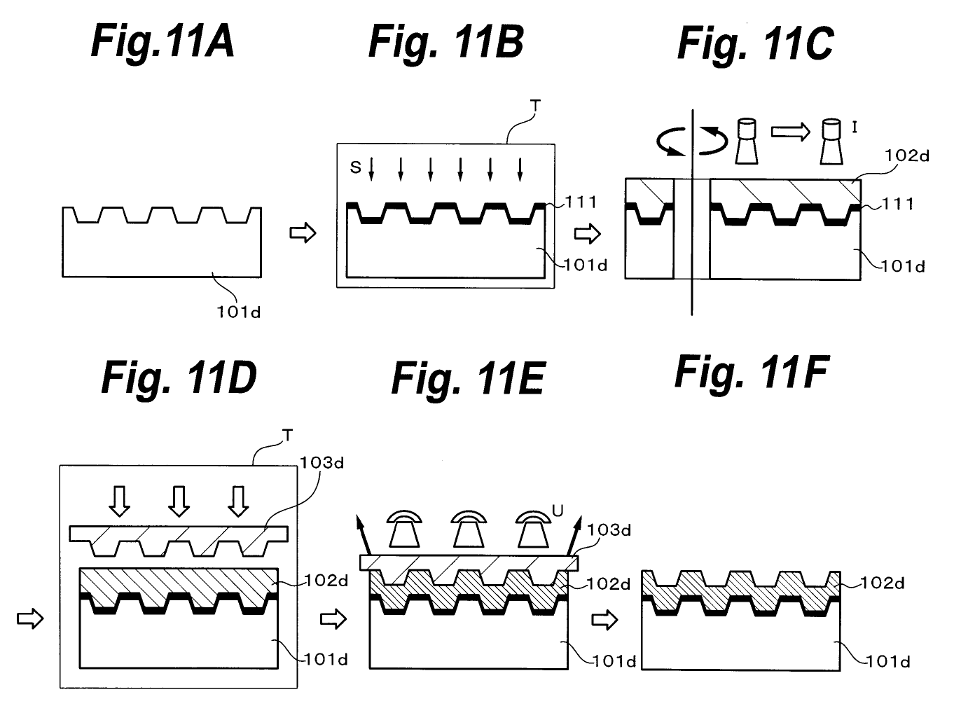

FIG. 12 is a schematic diagram showing a layout before the stamper is adhered in the concave/convex portions transfer step;

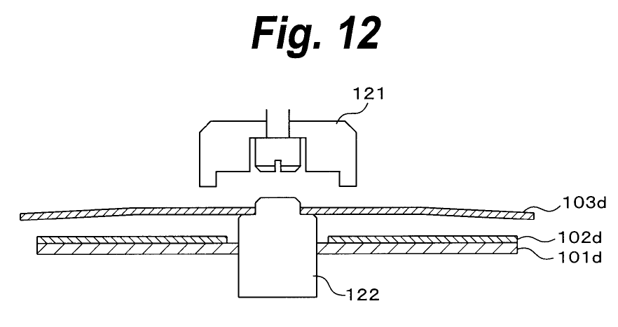

FIGS. 13A and 13B are schematic diagrams for explaining an example of generation of bubbles;

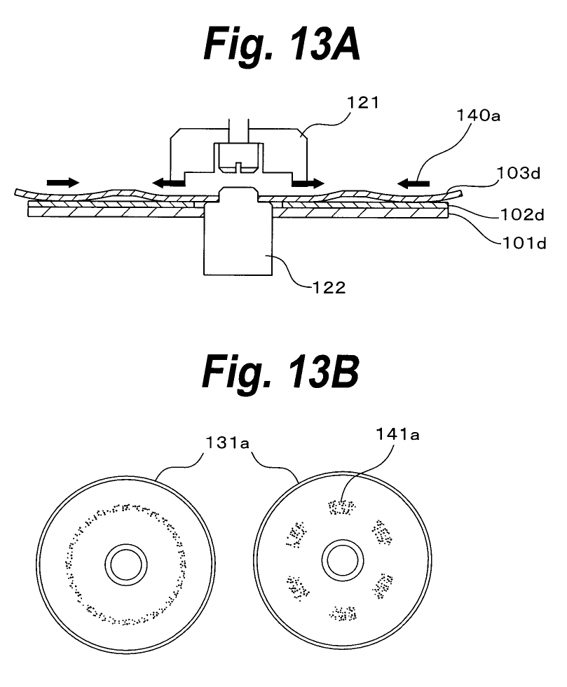

FIGS. 14A and 14B are schematic diagrams for explaining another example of the generation of the bubbles;

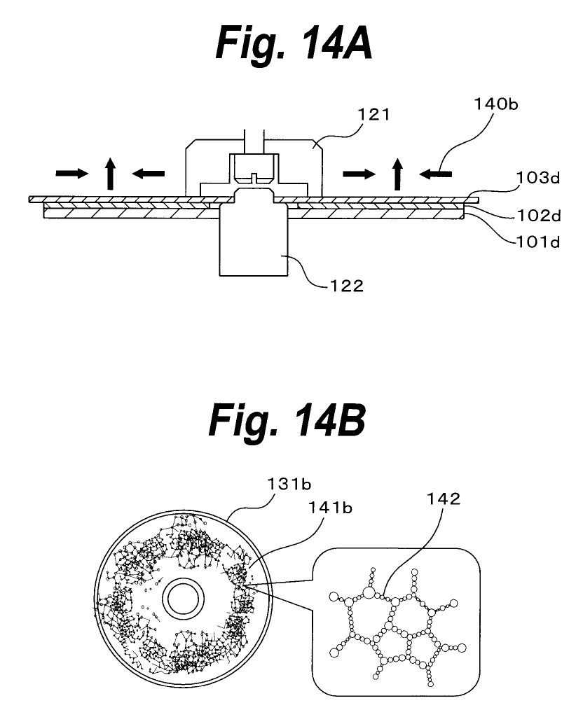

FIGS. 15A and 15B are schematic diagrams for explaining further another example of the generation of the bubbles; and

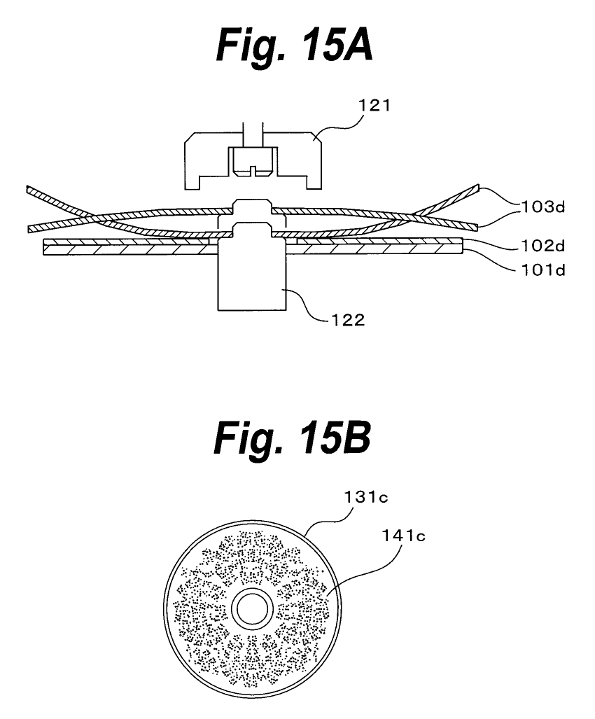

FIGS. 16A and 16B are schematic diagrams for explaining an example in which no bubbles are generated.

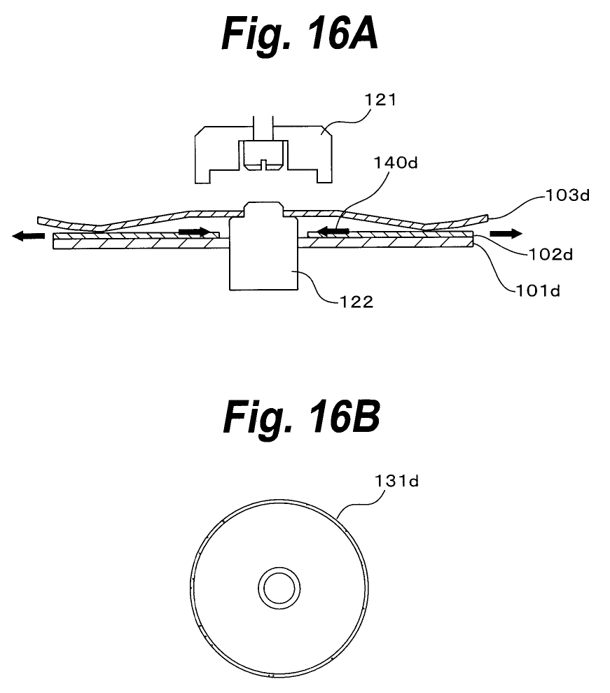

### DETAILED DESCRIPTION OF THE PREFERRED EMBODIMENTS

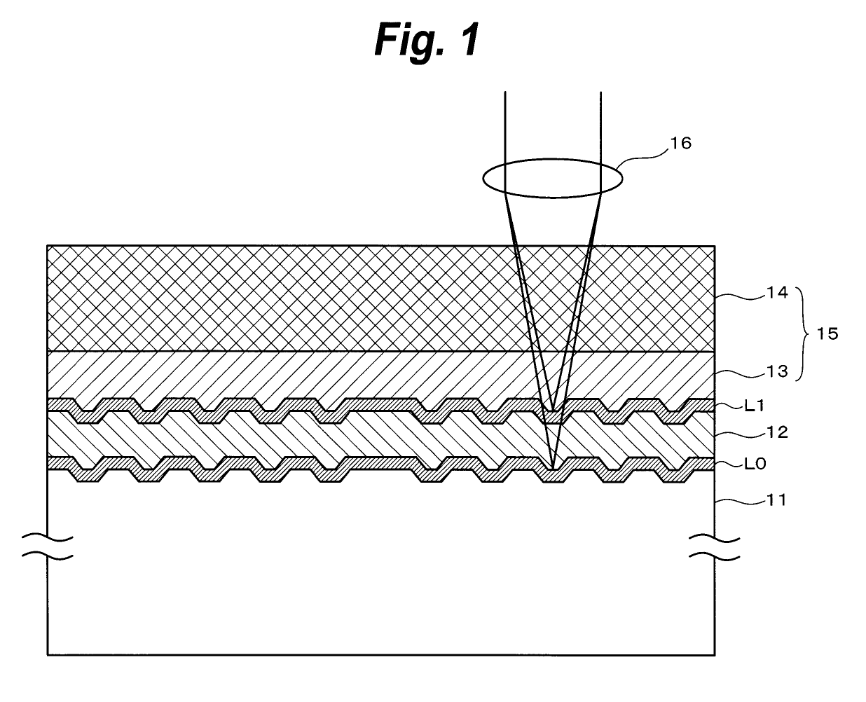

An embodiment of the invention will be described hereinbelow with reference to the drawings. An example of a high-density optical disk to which a manufacturing method according to an embodiment of the invention can be applied will be described with reference to FIG. 1.

In such an optical disk, an information signal is recorded and reproduced by irradiating a laser beam to an information recording layer from the side of a cover layer 15. For example, the laser beam having a wavelength of 400 to 410 nm is converged by an objective lens 16 having a numerical aperture (NA) of 0.84 to 0.86 and irradiated to either the L0 layer or the L1 layer serving as an information recording layer from the cover layer 15 side, so that the information signal is recorded or reproduced.

Such a high-density optical disk has a construction in which the L0 layer, an intermediate layer 12, the L1 layer, and the cover layer 15 are sequentially laminated onto a substrate 11. The cover layer 15 is formed by an adhesive layer 13 having a thickness of, for example, 15 μm and a polycarbonate (hereinafter, properly abbreviated to “PC”) sheet 14 having a thickness of, for example, 60 μm.

As a material of the substrate 11, a resin material such as polycarbonate resin, polyolefin resin, acrylic resin, or the like or glass may be used. It is desirable to use the resin material from a viewpoint of costs or the like. As a resin material, for example, cycloolefin polymer (“ZEONOR”, registered trademark) or PC may be used.

A molding method of the substrate 11 is not particularly limited but it is sufficient to use a method whereby a desired shape and smoothness of the surface of the substrate which is optically adequate can be obtained. For example, an injection molding method (injection method) or a photopolymer (2P method) method using an ultraviolet hardening resin may be used.

Each of the L0 layer and the L1 layer as information recording layers is a reflecting film or a recording film formed on the concave/convex portions of the substrate. If the optical disk is a read only type disk, for example, the reflecting film made of gold (Au), silver (Ag), a silver alloy, aluminum (Al), an aluminum alloy, or the like is formed. If the optical disk is a write once type disk, a recording film formed by sequentially laminating, for example, a reflecting film and a recording layer made of an organic pigment material is constructed. If the optical disk is a rewritable type disk, for example, a recording film formed by sequentially laminating a reflecting film, a lower layer dielectric layer, a phase-change recording layer, and an upper layer dielectric layer is constructed.

The intermediate layer 12 serving as a resin layer having a thickness of, for example, 25 μm is formed on the L0 layer formed on the substrate 11. The L1 layer is formed on the intermediate layer 12. As an intermediate layer 12, for example, an ultraviolet hardening resin may be used. An electron beam hardening resin may be used as an intermediate layer 12.

The cover layer 15 is formed on the L1 layer formed on the intermediate layer 12. The cover layer 15 is formed in order to protect the optical disk. The information signal is recorded and reproduced by, for example, converging the laser beam to the information recording layer through the cover layer 15.

As a cover layer 15, an adhesive layer and a PC sheet, a UV resin, or the UV resin and the PC sheet may be used. The cover layer 15 has a thickness of, for example, about 75 μm. For instance, the cover layer 15 is constructed by the adhesive layer 13 having a thickness of 15 μm and the PC sheet 14 having a thickness of 60 μm.

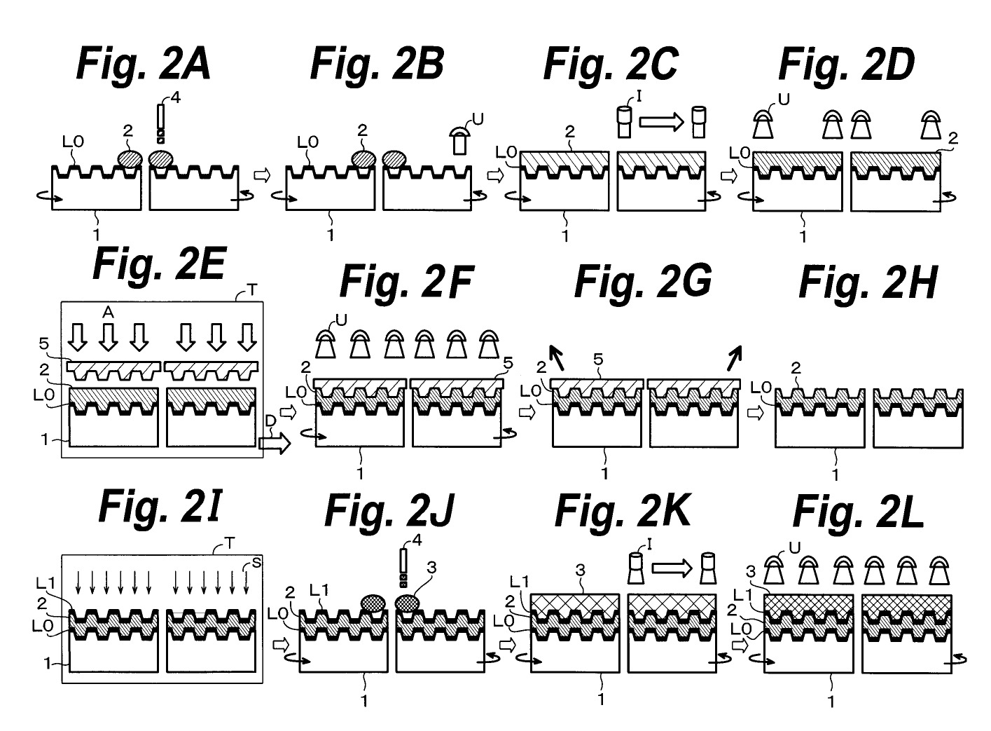

The manufacturing method of the optical disk according to the embodiment of the invention will now be described. FIGS. 2A to 2L schematically show the manufacturing method of the high-density optical disk according to the embodiment of the invention. First, as shown in FIG. 2A, while a substrate 1 is rotated, a UV resin 2 in a liquid state is dropped from a UV resin feeder 4 to a portion near the center of the L0 layer on one principal plane of the substrate 1 formed with the L0 layer.

By dropping the UV resin 2 while rotating the substrate 1, a centrifugal force is caused for the UV resin 2. The UV resin 2 is uniformly spread from the middle portion to the outer rim on the substrate, so that the surface of the substrate 1 is coated flat with the UV resin 2.

In this instance, as shown in FIG. 2B, a light spot of the ultraviolet rays may be irradiated to the outermost rim portion by using, for example, the ultraviolet irradiator (UV irradiator) U. By spot-irradiating the outermost rim portion, flowability of the UV resin 2 can be promoted, it is possible to prevent the outermost rim portion from getting thick, and uniformity of the thickness can be assured.

A method of coating the UV resin 2 is not limited to the spin-coating method but another method may be used. Specifically speaking, for example, a roll-coating, a die-coating, a dip-coating, a spray-coating, a casting, or the like may be used.

Subsequently, as shown in FIG. 2C, while the apparatus is operated so as to move the IR (Infrared Rays) lamp I from the inner rim toward the outer rim, infrared rays are irradiated to the UV resin 2. By irradiating the infrared rays as mentioned above, temperature distribution of the disk surface and the UV resin changes so that a temperature rises from the inner rim toward the outer rim, and viscosity can be controlled so as to promote the uniformity of the thickness of the UV resin 2.

Subsequently, as shown in FIG. 2D, the ultraviolet rays are irradiated to the UV resin 2 by using the UV irradiator U. In this instance, an irradiating intensity and irradiating time of the ultraviolet rays are adjusted so that the UV resin 2 enters a non-hardening state where the UV resin 2 is slightly hardened.

Subsequently, as shown in FIG. 2E, a stamper 5 is pressed to the UV resin 2 in a semi-hardening state. The stamper 5 is, for example, a transparent resin stamper molded by using a transparent resin such as ZEONOR (registered trademark) having such a nature as to transmit the light and concave/convex portions for transfer have been formed on one principal plane of the stamper.

By pressing the stamper 5 to the UV resin 2 in the semi-hardening state, the concave/convex portions of the stamper 5 are transferred to the UV resin 2 and the concave/convex portions are formed on one principal plane of the UV resin 2. In the embodiment, the stamper 5 is pressed to the UV resin 2 and the concave/convex patterns are transferred by the method using a pressure difference that is caused between almost the vacuum state and the state where an air pressure which is equal or higher than the atmospheric pressure is applied (hereinafter, referred to as a differential pressure laminating method).

According to the differential pressure laminating method, as shown in FIG. 2E, in the vacuum chamber T which has been set into the almost vacuum state by the vacuum evacuation as shown by the arrow D by using a vacuum pump, the stamper 5 is held in the state where it faces the UV resin 2 in the semi-hardening state. The inside of the chamber T is set to the vacuum and a closed space of a gap where the stamper 5 and the UV resin 2 face is also set to the vacuum of, for example, 50 Pa (Pascal).

Subsequently, since the vacuum state is broken and the atmospheric pressure is applied to the stamper 5 from the upper position as shown by arrows A, the stamper 5 is pressed to the UV resin 2 and adhered to the substrate 1 through the UV resin 2. Thus, the concave/convex portions of the stamper 5 are transferred to the UV resin 2 as an intermediate layer. Since the standard atmospheric pressure is equal to 101325 Pa, the air pressure of 101275 Pa (=101325 Pa−50 Pa) presses the stamper 5 downward as shown by the arrows A. The stamper 5 is pressed by a pressure of about 2000 times. In a range from the vacuum to the atmospheric pressure, the pressure changes with a certain leading time.

Subsequently, as shown in FIG. 2F, in the state where the stamper 5 has been adhered to the UV resin 2, the ultraviolet rays are irradiated to the UV resin 2 by using the UV irradiator U. Thus, the UV resin 2 formed with the concave/convex portions is completely hardened. After that, as shown in FIG. 2G, the stamper 5 is peeled off from the UV resin 2. Thus, the concave/convex portions are formed on the UV resin 2 as shown in FIG. 2H. As mentioned above, the concave/convex portions are formed onto the UV resin 2 as an intermediate layer by the differential pressure laminating method.

Subsequently, as shown in FIG. 2I, in the vacuum chamber T, the recording film, the reflecting film, or the like is formed on the concave/convex portions by, for example, the sputtering method. The arrow S in the diagram indicates the incident direction of the sputtering atom. The recording film, the reflecting film, or the like is formed on the concave/convex portions in accordance with the reproducing type optical disk, the WORM type optical disk, or the rewritable type optical disk. A film construction differs every optical disk.

Subsequently, as shown in FIG. 2J, the surface of the formed recording film or reflecting film is coated with a cover resin 3 as a cover layer by using the UV resin feeder 4. As a coating method, for example, the spin-coating method may be used. As mentioned above, the cover layer may be formed by adhering the PC sheet 14.

Subsequently, as shown in FIG. 2K, while the substrate 1 is rotated, the infrared rays are irradiated to the cover resin 3 by using the IR irradiator I while moving the IR irradiator I from the inner rim to the outer rim, thereby enabling the flattening of the cover resin 3 to be promoted.

Subsequently, as shown in FIG. 2L, by irradiating the ultraviolet rays to the cover resin 3 by using the UV irradiator U, the cover resin 3 is completely hardened. In this manner, the high-density optical disk according to the embodiment of the invention is manufactured.

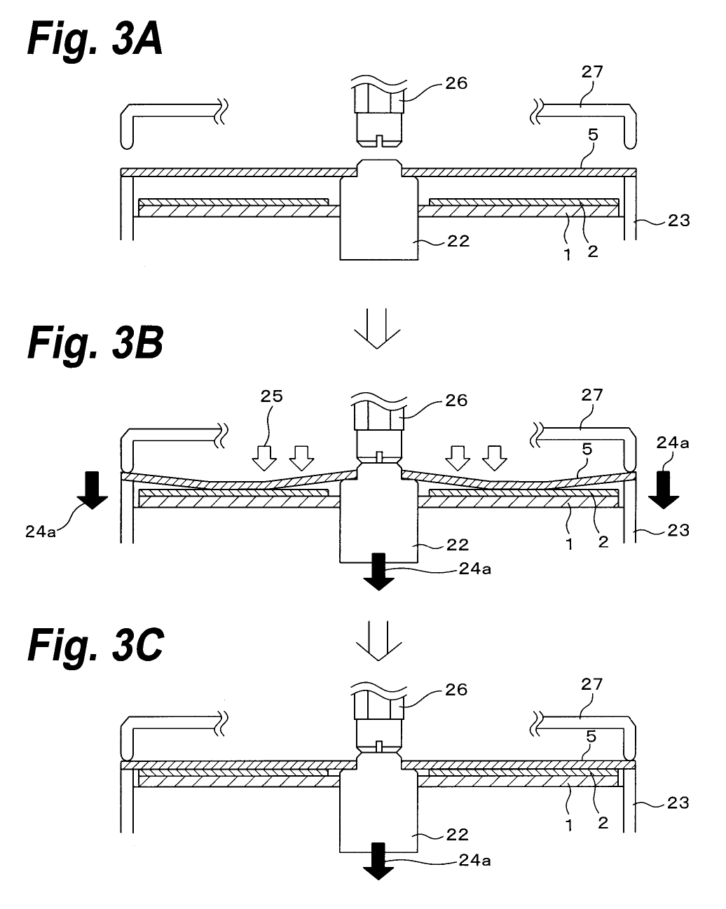

The foregoing differential pressure laminating method will now be described with reference to FIGS. 3A to 3C. As shown in FIG. 3A, a center opening of the transparent resin stamper 5 in which the concave/convex portions have been formed on one principal plane is fitted to a small-diameter portion of a front edge side of a centering pin constructing a supporting mechanism 22 of the inner rim side. The outer rim side of the stamper 5 is supported by a supporting mechanism 23 of the outer rim side. The centering pin penetrates a center opening of the substrate 1 coated flat with the UV resin 2 and is projected upward. The substrate 1 is put on a fixed table (not shown). The stamper 5 is arranged by the supporting mechanism 22 of the inner rim side and the supporting mechanism 23 of the outer rim side in such a manner that the stamper 5 has a predetermined interval from the substrate 1 and one principal plane of the stamper 5 faces one principal plane of the substrate 1 almost in parallel.

While holding the facing state of the stamper 5 and the substrate 1, they are disposed in, for example, the vacuum chamber (not shown) and, thereafter, the inside of the vacuum chamber is vacuum-evacuated by a vacuum pump. The vacuum chamber is evacuated to, for example, 5 to 500 Pa, preferably, 5 to 200 Pa. The inside of the vacuum chamber and a gap between the substrate 1 and the stamper 5 which face are set into the vacuum state.

Subsequently, as shown in FIG. 3B, when the vacuum in the vacuum chamber is broken and the chamber is released to the atmospheric pressure, the closed space formed by the substrate 1 and the stamper 5 is pressurized by a differential pressure between the vacuum and the atmospheric pressure. While the shape of the stamper 5 is deformed, the stamper 5 is pressed to the UV resin 2. As shown in FIG. 3C, the substrate 1 and the stamper 5 are adhered through the UV resin 2.

When the vacuum is broken, the holding state of the supporting mechanisms to hold the interval between the stamper 5 and the substrate 1 is cancelled simultaneously with the release of the atmospheric pressure. By the cancellation of the supporting mechanisms synchronized with the release of the atmospheric pressure, the stamper 5 is adhered onto the substrate 1 in the state where its middle portion is bent downward. When the middle portion of the stamper 5 is bent downward, the simultaneous adhesion of the substrate 1 in both directions can be executed, that is, the adhesion in the direction from the middle portion to the inner rim portion and the adhesion in the direction from the middle portion to the outer rim portion can be simultaneously executed. Thus, the capture of the bubbles can be prevented and the adhesion in which the generation of the burs in the outer rim portion is small can be performed.

The cancellation of the supporting mechanisms is made by controlling the supporting mechanism 22 of the inner rim side of the stamper 5 and the supporting mechanism 23 of the outer rim side. For example, the supporting mechanisms are controlled so as to simultaneously move the supporting mechanism 22 of the inner rim portion and the supporting mechanism 23 of the outer rim portion downward in the direction shown by arrows 24a at a predetermined speed, for example, 2 mm/sec synchronously with the release of the atmospheric pressure. The supporting mechanism 22 of the inner rim portion operates so as to be pressed downward by a centering pin depressing mechanism 26. The supporting mechanism 23 of the outer rim portion operates so as to be pressed downward by an outer rim pressure ring depressing mechanism 27.

By controlling as mentioned above, the middle portion of the stamper 5 is bent downward and come into contact with the UV resin 2. After that, the stamper 5 is adhered to the substrate 1. By forming the state where the middle portion of the stamper 5 is bent and adhering the substrate 1 and the stamper 5, the portion in the inner rim direction of the substrate 1 and the portion in the outer rim direction are simultaneously adhered and the generation of the bubbles can be reduced.

The adhering state in which the generation of the burs in the outer rim portion of the disk is small can be formed. Further, if the bubble is brought in, since the gas is compressed by the differential pressure between the vacuum and the atmospheric pressure shown by arrows 25, a volume of the mixed bubble decreases. Thus, the optical disk of high quality which does not exert an adverse influence on recording/reproducing efficiency of the signal can be manufactured.

For example, since the atmospheric pressure is equal to about 101325 Pa, the pressing pressure of about 2000 times can be applied to the stamper 5 by the differential pressure between the vacuum pressure of, for example, about 50 Pa and the atmospheric pressure. Therefore, even if the bubble was mixed between the stamper 5 and the substrate 1, since a volume of the bubble is decreased to 1/2000, no adverse influence is exerted on recording/reproducing characteristics of the signal.

Specifically speaking, for example, if the bubble having a diameter of 30 μm entered the gap between the stamper 5 and the substrate 1, the diameter is decreased to 2.5 μm by the differential pressure. Therefore, the optical disk of the high quality which does not exert an adverse influence on the stable recording and reproduction of the signal can be manufactured.

In the embodiment of the invention, the vacuum chamber is changed from almost the vacuum state to the state where the atmospheric pressure is applied. Further, the invention is not limited to the atmospheric pressure but the vacuum chamber may be forcedly pressurized to the atmospheric pressure or higher. In such a case, since a larger pressing force is generated, the volume of the entering bubble can be more decreased.

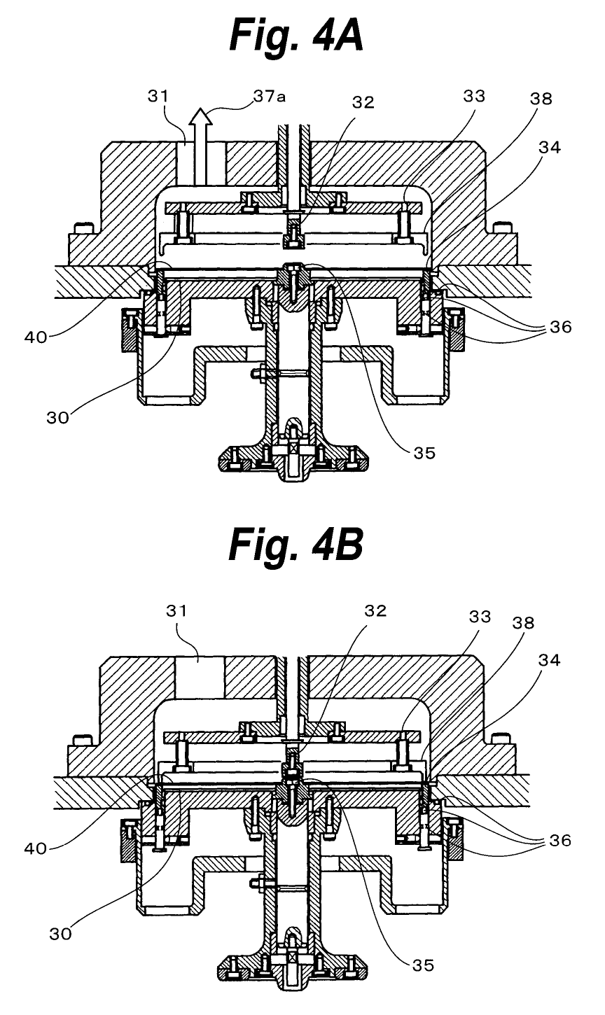

FIGS. 4A and 4B, 5A and 5B, and 6 show more specific constructional examples of the differential pressure laminating apparatus and an operating state in a concave/convex portions forming step. Reference numeral 30 denotes a disk substrate and 40 indicates a transparent resin stamper. The differential pressure laminating apparatus is constructed by: a vent hole 31 for vacuum evacuation and leakage adapted to flow the air into and out of the apparatus; a centering pin depressing mechanism 32 which is elevated up and down; an outer rim pressure ring depressing mechanism 33 which is elevated up and down; an outer rim ring 34 for supporting the outer rim of the stamper 40; a centering pin 35 for supporting a center portion of the stamper 40; an O-ring 36 as a member for sealing the inside of the chamber; and an outer rim pressure ring 38 for pressing an outer rim edge of the stamper 40.

First, FIG. 4A shows the state where a UV resin coating surface of the disk substrate 30 and a concave/convex portions forming surface of the stamper 40 are arranged so as to face and the vacuum evacuation of the chamber is started. A center opening of the stamper 40 is fitted to a stairway portion of a small-diameter portion of a front edge of the centering pin 35. The disk substrate 30 which has already been coated with the UV resin is put onto a disk-shaped supporting table and the centering pin 35 penetrates a center opening of the disk substrate 30. Positioning of the center and setting of an opposite interval are made by the centering pin 35 with the stairway portion. To enable the adhesion and the peel-off of the stamper 40 and the disk substrate 30 to be easily performed, an outer diameter of the stamper 40 is set to be slightly larger than that of the disk substrate 30. As for the vacuum evacuation, the inside of the chamber is set to the vacuum state by evacuating the air through the bent hole 31 in the direction shown by an arrow 37a.

Subsequently, as shown in FIG. 4B, the centering pin 35 and the outer rim ring 34 are depressed by downwardly moving the centering pin depressing mechanism 32 and the outer rim pressure ring depressing mechanism 33. By this downward operation, the stamper 40 is moved to an intermediate position which is slightly lower than an initial position. After that, the air is fed into the chamber from the bent hole 31, thereby starting the release to the atmosphere.

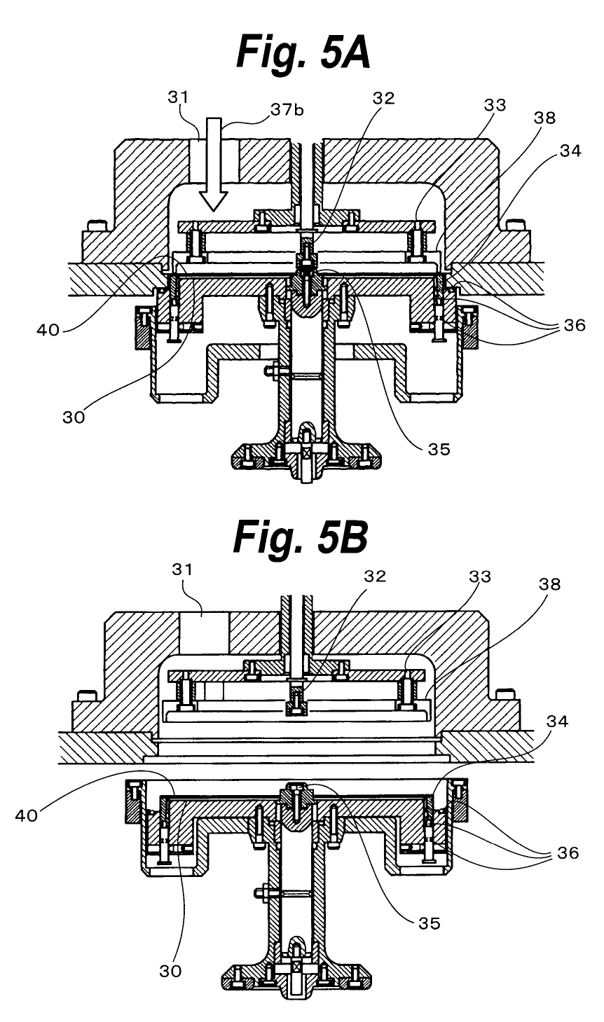

Subsequently, as shown in FIG. 5A, when the air flows into the chamber from the bent hole 31 in the direction shown by an arrow 37b and the release of the chamber to the atmosphere is finished, the air pressure in the chamber becomes the atmospheric pressure. A force adapted to press the stamper 40 is generated by the differential pressure between the vacuum and the atmospheric pressure. The stamper 40 is adhered to the substrate 30 and the concave/convex portions are transferred to the UV resin as an intermediate layer coated on the substrate 30.

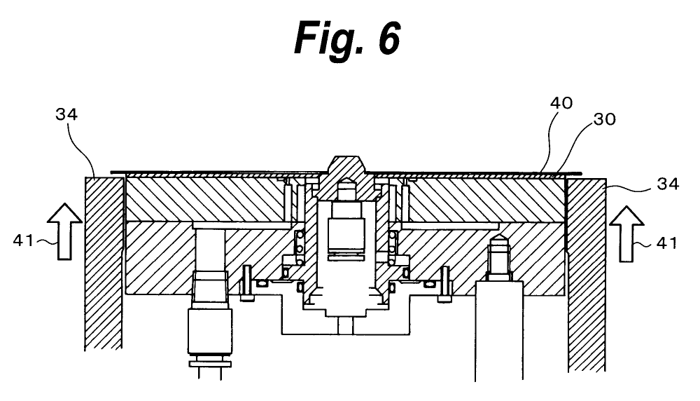

Subsequently, as shown in FIG. 5B, a lower portion of the apparatus is moved downward and the substrate 30 and the stamper 40 which have been vacuum-adhered are taken out of the chamber. After that, the UV resin is completely hardened by irradiating the ultraviolet rays through the stamper 40 and the stamper 40 is peeled off from the substrate 30 as shown in, for example, FIG. 6.

FIG. 6 shows the operation of the apparatus when the stamper is peeled off. FIG. 6 is a partially enlarged diagram of the differential pressure laminating apparatus obtained after the stamper 40 was adhered to the substrate 30. As shown in FIG. 6, an outer diameter portion of the stamper 40 is projected over the outer rim ring 34. By moving the outer rim ring 34 in the direction (upper direction) shown by an arrow 41, the stamper 40 is peeled off from the substrate 30. In this manner, the concave/convex portions can be formed onto the intermediate layer laminated on the substrate 30.

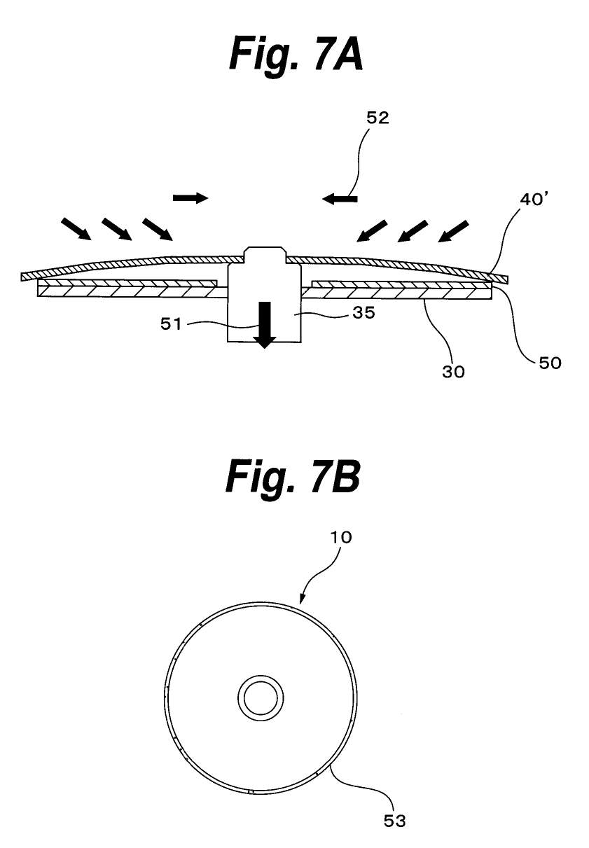

Although the flat stamper has been used as a stamper in the above example, for instance, the concave/convex portions can be also transferred by using a curved stamper. FIGS. 7A and 7B schematically show the transfer in the case of using the curved stamper.

As shown in FIGS. 7A and 7B, in the case of using a curved stamper 40′, a pressure is applied to the stamper 40′ as shown by arrows 52, so that the stamper 40′ and the substrate 30 coated with a UV resin 50 are adhered.

Thus, the apparatus can be controlled so as to generate bubbles 53 only in the outer rim portion and an optical disk 10 of high quality having excellent recording and reproducing characteristics can be manufactured. The curved stamper 40′ can be manufactured by controlling molding conditions upon injection molding.

According to the creation of the concave/convex portions using the curved stamper 40′, when the differential pressure lamination is executed, the stamper and the substrate can be easily arranged at positions suitable for suppressing the generation of the bubbles, so that the construction can be simplified.

That is, in the outer rim portion, since the UV resin 50 of the portion where the curved stamper 40′ and the substrate 30 are come into contact with each other functions like an O-ring, merely by arranging the two-stage centering pin 35 for closing a center hole portion while performing centering of both of them, they can be merely arranged at the positions suitable for suppressing the generation of the bubbles.

By moving the centering pin 35 downward as shown by an arrow 51 synchronously with the differential pressure lamination due to the release to the atmosphere, the curved stamper 40′ is adhered to the substrate 30 without generating the bubbles which exert an adverse influence on the recording/reproducing characteristics.

Although the release to the atmosphere has been performed almost from the vacuum state according to the foregoing differential pressure laminating method, in place of releasing to the atmosphere, it is also possible to introduce the compressed air (a gas other than the air can be also used) into the chamber and forcedly pressurize by the air pressure which is equal to or higher than the atmospheric pressure. As a compressed air, the air of about a middle pressure (10 to 3 kg/cm²) which is used in an air pressure system that is used in a factory or the like or the air of a low pressure (3 kg/cm² or lower) is used. The compressed air is produced by a compressor, accumulated in a tank or the like, and supplied to the differential pressure laminating apparatus through pipes, control valves, and the like.

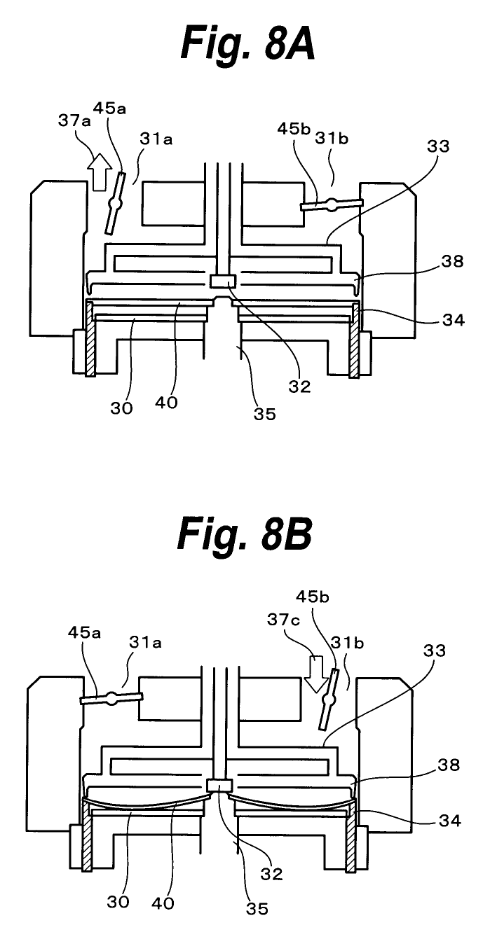

The differential pressure laminating method of pressurizing by the air pressure which is equal to or higher than the atmospheric pressure can be also realized by steps and an apparatus similar to those of the differential pressure laminating method of performing the release to the atmosphere mentioned above. The differential pressure laminating method of pressurizing will be described with reference to a differential pressure laminating apparatus of FIGS. 8A and 8B. In the apparatus of FIGS. 8A and 8B, component elements similar to those in FIGS. 4A, 4B, 5A, and 5B are designated by the same reference numerals.

In FIGS. 8A and 8B, the chamber has a vent hole 31a for vacuum evacuation, a vent hole 31b for forced pressurization, and valves 45a and 45b to open and close the vent holes. For the vacuum evacuation and the pressurization, it is also possible to use one vent hole in common and switch the vacuum evacuation and the pressurization by controlling an external valve.

First, the disk substrate 30 having the L0 layer is coated flat with the UV resin and, as shown in FIG. 8A, they are arranged so that the UV resin coating surface of the disk substrate 30 and the forming surface of the concave/convex portions of the stamper 40 face. The center opening of the stamper 40 is fitted to the stairway portion of the small-diameter portion of the front edge of the centering pin 35. The disk substrate 30 which has already been coated with the UV resin is put onto the disk-shaped supporting table and the centering pin 35 penetrates the center opening of the disk substrate 30.

The outer diameter of the stamper 40 is set to be slightly larger than that of the disk substrate 30. The concave/convex portions have preliminarily been formed on the stamper so that the forming surface of the concave/convex portions faces downward. The stamper 40 is set into the vacuum chamber and vacuum-evacuated. The vacuum evacuation is executed by opening the valve 45a, closing the valve 45b, and evacuating the air from the vent hole 31a in the direction shown by the arrow 37a.

Subsequently, the centering pin 35 and the outer rim ring 34 are depressed by downwardly moving the centering pin depressing mechanism 32 and the outer rim pressure ring depressing mechanism 33. By this downward depressing operation, the stamper 40 is moved to the intermediate position which is slightly lower than the initial position. In the case of using the curved stamper 40′ shown in FIGS. 7A and 7B, the curved stamper 40′ is moved until the outer rim portion of the curved stamper 40′ and the outer rim edge portion of the disk substrate 30 are come into contact with each other through the UV resin.

Subsequently, as shown in FIG. 8B, the valve 45a is closed and the valve 45b is opened, thereby breaking the vacuum in the chamber and allowing the compressed air to flow into the chamber from the vent hole 31b as shown by the arrow 37c. The stamper 40 and the disk substrate 30 are adhered by the forced pressurization using the compressed air. In the case of using the curved stamper 40′, a closed space formed by the curved stamper 40 and the disk substrate 30 is pressurized by the differential pressure between the vacuum and the forced pressurization, the curved stamper 40′ is deformed and adhered. Synchronously with the pressurizing operation, the supporting mechanisms which have held the stamper 40 and the disk substrate 30 with a proper gap are released. That is, the centering pin 35 is moved downward at a predetermined speed.

In this instance, as shown in FIG. 8B, the state where the middle portion of the stamper 40 is bent downward is formed by controlling the mechanism for holding the inner rim portion of the stamper 40, the mechanism for holding the outer rim portion of the stamper 40, and the mechanism for moving the stamper 40. When the middle portion of the stamper 40 is bent downward, the simultaneous adhesion of the disk substrate 30 in both directions can be performed, that is, the adhesion in the direction from the middle portion to the inner rim portion and the adhesion in the direction from the middle portion to the outer rim portion can be simultaneously executed. Thus, the capture of the bubbles can be prevented and the adhesion in which the generation of the burs in the outer rim portion is small can be performed. The concave/convex portions are transferred to the UV resin as an intermediate layer coated on the substrate 30. The pressurization by the compressed air is executed in a very short time. After the stamper 40 and the substrate 30 were completely adhered, the chamber is released to the atmosphere through at least either the vent hole 31a or the vent hole 31b.

Subsequently, the lower portion of the apparatus is moved downward and the substrate 30 and the stamper 40 which have been vacuum-adhered are taken out of the chamber. After that, by irradiating the ultraviolet rays through the stamper 40, the UV resin is completely hardened. Subsequently, the stamper 40 is peeled off from the substrate 30.

It is also possible to irradiate the ultraviolet rays in the holding state of the pressurization without releasing the chamber to the atmosphere after the adhesion.

As mentioned above, if the compressed air is used, the pressure of 300000 Pa which is 6000 times as large as 50 Pa can be applied from almost the vacuum state of, for example, 50 Pa, so that a volume of the mixed bubble can be reduced into 1/6000. The large pressure can be rapidly applied at the initial stage of the breakdown of the vacuum. When comparing with the release to the atmosphere, it is possible to prevent the adhesion from becoming insufficient and the adhesion can be stably and preferably performed.

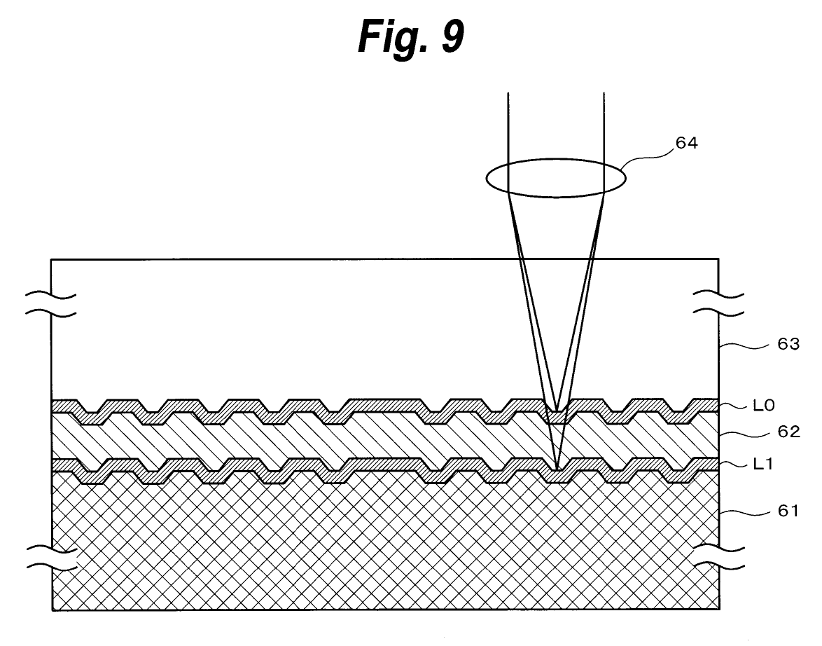

Although the embodiment of the invention has been described with respect to the high-density optical disk with the construction in which the L0 layer, the intermediate layer, the L1 layer, and the cover layer have sequentially been laminated onto the substrate, the invention is not limited to such an example. For instance, as shown in FIG. 9, the invention can be also applied to an optical disk constructed by sequentially laminating a first substrate 61, the L1 layer, an intermediate layer 62, the L0 layer, and a second substrate 63. Each of the first substrate 61 and the second substrate 63 is made of, for example, PC. The intermediate layer 62 is made of, for example, a UV resin and has a thickness of 50 μm.

In the optical disk shown in FIG. 9, the recording and reproduction of the information signal are executed by, for example, irradiating the laser beam from the second substrate 63 side to information recording layers. For instance, the recording and reproduction of the information signal are executed by a method whereby the laser beam having a wavelength of 650 to 665 nm is converged by an objective lens 64 having a numerical aperture of 0.64 to 0.66 and irradiated to the L0 layer and the L1 layer as information recording layers from the second substrate 63 side.

Although the embodiment of the invention has specifically been described above, the invention is not limited to the foregoing embodiment of the invention but many modifications and variations are possible within the scope of the invention without departing from the spirit of the invention. For example, the invention can be also applied to the case where the stamper is made of a metal material such as nickel. If the information recording layer is the recording film, since the light is hardly transmitted, it is necessary that the ultraviolet rays for hardening the resin are irradiated through a transparent stamper. However, if the information recording layer is the reflecting film, since the light is slightly transmitted, the ultraviolet rays for hardening the resin can be irradiated from the substrate side. In this case, it is unnecessary for the stamper to have the light permeability.

Although the embodiment of the invention has been described with respect to the optical disk having the two information recording layers, the invention can be also applied to an optical disk having three or more information recording layers. It is also possible to form the transfer layer onto a substrate without the signal by the method of the invention and form the disk having one information recording layer. It is also possible to form the transfer layer onto a transparent substrate without the reflecting layer and the recording film although it has the layers with the signal concave/convex portions by the method of the invention and form the disk having one information recording layer. For example, the disk having one information recording layer may be manufactured by recycling a substrate having defective signal transfer performance, a surplus substrate, or the like.

It should be understood by those skilled in the art that various modifications, combinations, sub-combinations and alterations may occur depending on design requirements and other factors insofar as they are within the scope of the appended claims or the equivalents thereof.

What is claimed is:

1. A manufacturing method of an optical disk in which an information recording layer is formed onto a resin layer laminated on one surface of a substrate, comprising the steps of:
coating said resin layer onto the surface of said substrate;
arranging said substrate and a stamper into a chamber so that one surface of said resin layer and one surface of the stamper on which concave/convex portions have been formed face almost in parallel;
setting said chamber into an almost vacuum state while holding the facing state of said substrate and said stamper;
changing said chamber from said almost vacuum state to a state of an atmospheric pressure or higher, overlaying said substrate and said stamper, and pressing said stamper by a differential pressure between a pressure in said almost vacuum state and a pressure which is equal to or higher than said atmospheric pressure, thereby adhering said substrate and said stamper and transferring said concave/convex portions to said resin layer; and
hardening the resin layer to which said concave/convex portions have been transferred.

2. A method according to claim 1, wherein concave/convex portions of said information recording layer have previously been formed on the surface of said substrate.

3. A method according to claim 1, wherein said resin layer is an ultraviolet hardening resin, said stamper is overlaid to said resin layer in a non-hardening state, and by irradiating ultraviolet rays to said resin layer, said resin layer is hardened.

4. A method according to claim 3, wherein said stamper has light permeability, and said resin layer is hardened by the ultraviolet rays which are irradiated through said stamper.

5. A method according to claim 3, wherein said substrate has light permeability, and said resin layer is hardened by the ultraviolet rays which are irradiated through said substrate.

6. A manufacturing apparatus of an optical disk, comprising:
supporting means holding a substrate coated with a resin layer on one surface and a stamper in a chamber so that said resin layer and one surface of said stamper on which concave/convex portions have been formed face; and
control means setting said chamber into an almost vacuum state while holding the facing state of said substrate and said stamper and changing said chamber from said almost vacuum state to a state of an atmospheric pressure or higher,
wherein by cancelling the holding state of said stamper and said substrate synchronously with the change in air pressure, said substrate and said stamper are overlaid, and by pressing said stamper by a differential pressure between a pressure in said almost vacuum state and a pressure which is equal to or higher than said atmospheric pressure, said substrate and said stamper are adhered and said concave/convex portions are transferred to said resin layer.

7. An apparatus according to claim 6, wherein concave/convex portions of an information recording layer have previously been formed on the surface of said substrate.

8. An apparatus according to claim 6, wherein said resin layer is an ultraviolet hardening resin, said stamper is overlaid to said resin layer in a non-hardening state, and by irradiating ultraviolet rays to said resin layer, said resin layer is hardened.

9. An apparatus according to claim 8, wherein
said stamper has light permeability, and
said resin layer is hardened by the ultraviolet rays which are irradiated through said stamper.

10. An apparatus according to claim 8, wherein
said substrate has light permeability, and
said resin layer is hardened by the ultraviolet rays which are irradiated through said substrate.

11. An apparatus according to claim 6, wherein said stamper has a curved shape.

12. A manufacturing apparatus of an optical disk, comprising:
a supporting unit holding a substrate coated with a resin layer on one surface and a stamper in a chamber so that said resin layer and one surface of said stamper on which concave/convex portions have been formed face; and
a controller setting said chamber into an almost vacuum state while holding the facing state of said substrate and said stamper and changing said chamber from said almost vacuum state to a state of an atmospheric pressure or higher,
wherein by cancelling the holding state of said stamper and said substrate synchronously with the change in air pressure, said substrate and said stamper are overlaid, and by pressing said stamper by a differential pressure between a pressure in said almost vacuum state and a pressure which is equal to or higher than said atmospheric pressure, said substrate and said stamper are adhered and said concave/convex portions are transferred to said resin layer.
